(19) United States
(12) Patent Application Publication
(10) Pub. No.: US 2015/0309228 A1
(43) Pub. Date: Oct. 29, 2015

(54) A SPECTRALLY SELECTIVE PANEL

(71) Applicant: TROPIGLAS TECHNOLOGIES LTD, Yokine, Western Australia (AU)

(72) Inventors: Mikhail Vasiliev, Quinns Rocks, Western Australia (AU); Kamal Alameh, Rivervale, Western Australia (AU); Victor Rosenberg, Yokine, Western Australia (AU)

(21) Appl. No.: 14/649,289

(22) PCT Filed: Dec. 3, 2013
(86) PCT No.: PCT/AU2013/001401

§ 371 Date: Jun. 3, 2015

(30) Foreign Application Priority Data
Dec. 3, 2012 (AU) 2012905254
Jun. 18, 2013 (AU) 2013902207

(51) Int. Cl. G02B 5/28; F21S 11/00; H01L 31/054; G02B 5/20

(52) U.S. Cl. CPC G02B 5/282; G02B 5/201; G02B 5/283; F21S 11/007; H01L 31/0549

(57) ABSTRACT

The present disclosure provides a spectrally selective panel that is at least partially transmissive for radiation having a wavelength within the visible wavelengths range. The panel has a receiving surface for receiving incident radiation and comprises at least one reflective component that is arranged to reflect a portion of received incident radiation that penetrated through a depth portion of the panel to the reflective component. The at least one reflective component may comprise a series of reflective portions that are inclined relative to the receiving surface such that at least a portion of the reflected radiation is re-directed within and along the panel. Certain embodiments comprise means to redirect internally reflected light for illuminating a room or region.

### FIELD OF THE INVENTION

The present invention relates to a spectrally selective panel.

### BACKGROUND OF THE INVENTION

Overheating of interior spaces is a problem that can be overcome using air conditioners. A large amount of electrical energy is globally used to cool interior spaces. The majority of electrical energy is generated using non-sustainable sources, which is of increasing environmental concern. Heat energy associated with solar radiation is transmitted through windowpanes and contributes to the overheating of the interior spaces.

### SUMMARY OF THE INVENTION

The present invention provides in a first aspect a spectrally selective panel that is at least partially transmissive for radiation having a wavelength within the visible wavelengths range, the panel having a receiving surface for receiving incident radiation and comprising at least one reflective component that is arranged to reflect a portion of received incident radiation that penetrated through a depth portion of the panel to the reflective component, the at least one reflective component comprising a series of reflective portions that are inclined relative to the receiving surface such that at least a portion of the reflected radiation is re-directed within the panel.

The spectrally selective panel may comprise at least two panel components and the reflective component may be positioned between or sandwiched between the panel components. The reflective component may form an interface with each panel component. The reflective component may also form a part of at least one of two panel components.

The spectrally selective panel may comprise first and second component panels that each have structured inner surfaces at which respective first and second panel portions mate (directly or indirectly). The respective first and second panel components may be joined (directly or indirectly) by a suitable material (a suitable epoxy or adhesive, a polymeric material or a lamination layer).

In one specific embodiment each of the first and second panel components have structured inner surfaces at which respective first and second panel portions mate (directly or indirectly) and at which the reflective component is formed.

In an alternative embodiment the first or the second panel component has a structured inner surface at which the reflective component is formed and a space between mating first and second panel components may be filled with a suitable material, such as the epoxy or lamination material.

The panel components may be substantially flat and may comprise or may be formed form glass or a suitable polymeric material. The spectrally selective panel may have substantially flat exterior surfaces. The spectrally selective panel may be provided in the form of, or may form a part of, a window pane. For example, the spectrally selective panel may be provided in the form of, or may comprise, a windowpane of a building, car, boat or any other object that comprises windows or blinds.

The at least one reflective component may be arranged to reflect at least a portion of incident radiation within an infrared (IR) wavelength band and typically also within an ultraviolet (UV) wavelength band while being at least partially transmissive for radiation having a wavelength within the visible wavelength band. The at least one reflective component may alternatively or additionally also be arranged to reflect a portion of incident radiation within the visible wavelength band.

In one embodiment the at least one reflective component comprises an optical interference coating that is positioned at or in the proximity of the reflective portions and that results in the above-described spectral properties. The optical interference coating may comprise a single an edge filter, comprising a plurality of material layers. The edge filter may comprise one or more stacks of material layers, the at least one stack comprising material layers of at least two different material properties. A first stack may have a first sequence of the material layers and a second stack may have a second sequence of material layers and wherein the first and second sequences are different sequences. At least two of the stacks may comprise similar or substantially identical material layers, but may have different layer sequences (different “repetition indices”).

In addition, the spectrally selective panel may also comprise a luminescent material that is arranged to absorb at least a portion of incident and/or reflected radiation and emit radiation by luminescence.

As mentioned above, the spectrally selective panel in accordance with embodiments of the present invention may be used for various purposes. The spectrally selective panel may be arranged such that a portion of the incident radiation is redirected by the reflective component to edges of the spectrally selective panel. For example, the spectrally selective panel may form a part of a system that comprises a photovoltaic cell or thermoelectric cell that is positioned at an edge of the spectrally selective panel and arranged to receive a portion of the redirected radiation. Alternatively, the system may for example comprise an optical coupler and a light extractor. The optical coupler may be positioned at an edge of the spectrally selective panel and may be arranged to direct a portion of the radiation from the edge to a light extractor for illumination of an interior region.

In one embodiment the spectrally selective panel is arranged such that at least the majority of incident radiation within an infrared (IR) wavelength band and/or within an ultraviolet (UV) wavelength band is reflected by the reflective component.

At least some variations of this embodiment provide the advantage that the panel may be used as a heat shield. Redirected radiation may be collected and used for generation of electricity or illumination elsewhere.

The spectrally selective panel may be arranged such that redirection, trapping, routing, and/or waveguiding of radiation within the spectrally selective panel is assisted by total internal reflection at interfaces. While complete trapping of incident light energy cannot be achieved using a combination of passive structures in the panel, suitable designed structures promote effective redirection of a significant portion of the incident light energy which propagates within the panel.

The reflective portions of the reflective component may be inclined by any suitable angle relative to the receiving surface of the panel. In one embodiment the reflective portions are planar, but may alternatively also have another suitable shape. The reflective portions may have a flat surface, but may also have a structured or rough surface that typically is sufficiently smooth to represent a surface that has optical properties that approximate those of a flat surface. At least some of the reflective portions may be inclined in a uniform manner.

The reflective portions may be inclined such that, for a predetermined orientation of the panel, at least the majority or all radiation of a spectrally selected wavelengths range (such as IR and/or UV and/or visible radiation having a selected wavelengths range) that is incident at an angle greater than 25, 30, 35, 40, 45, 50, 60 or 70 degrees relative to a surface normal of the receiving surface is redirected within and typically along the panel.

In a specific example the spectrally selective panel is arranged such that at least the majority of radiation of a spectrally selected wavelengths range that is in use incident at an angle of incidence within the range of 25-90 degrees, 30-90 degrees, 35-90 degrees, 40-90 degrees, 45-90 degrees, 50-90 degrees, 60-90 degrees or 70-90 degrees within a plane containing a normal of the receiving surface is redirected within the panel.

The reflective component may comprise any number of reflective portions. The reflective portions may for example be arranged in a “saw-tooth” arrangement. Each reflective portion may have a prism-shaped cross-sectional shape in a plane perpendicular to the receiving surface. Further, each reflective portion typically is provided in the form of a strip of any suitable length (for example a length with the range of a few centimetres to a few metres), such as a length that extends along at least a portion of, or the entire, length or width of the spectrally selective panel. Each reflective portion may have any suitable width, such as a width larger than 0.05 mm, 0.1 mm, 0.5 mm, 1 mm, 5 mm, 10 mm, 20 mm, 50 mm or even larger than 100 mm.

In one embodiment the reflective portions are uniformly inclined. In an alternative embodiment at least one of the reflective portions may be inclined at an angle that is different to an angle of inclination of other reflective portions. Further, a first plurality of reflective portions may be inclined in a first manner and a second plurality of the reflective portions may be inclined in a second manner that may be opposite the first manner. For example, the reflective portions may be positioned on a common plane and the reflective portion on a first area of the common plane may be inclined in the first manner and the reflective portion of a second area of the common plane may be inclined in the second manner.

The reflective portions of the reflective component may be formed in a moulding process and may be integrally formed. Alternatively, at least some of the reflective portions may be formed separately and then assembled to form at least a portion of the reflective component. The reflective portions may comprise any suitable material, including glass, ceramic materials, and polymeric materials, suitable metallic materials and metal-oxides.

In one embodiment each reflective portion comprises is a first reflective portion and the at least one reflective component further comprises second reflective portions and wherein the first and second reflective portions form a series of reflective portions positioned on a common plane and in which the first and second reflective portions alternate. The first reflective portions may be inclined by a first angle relative to the receiving surface and the second reflective portions may be inclined by a second angle relative to the first reflective portions. The first angle may be of the order of 5-20, 7-17, 9-15, 10-13 such as 12 degrees. The second angle of the order of 100-150, 101-111, 103-109, 105-107 such as 106 degrees with adjacent first reflective portions. In this embodiment adjacent first and second reflective portions consequently may be arranged such that a base plane of the reflective component together with the adjacent first and second reflective portions have a substantially triangular cross-sectional shape that may have a first angle of 12±5 degrees, a second angle of 106±5 degrees and a third angle of 62±5 degrees.

In one embodiment the reflective portions have a non-planar reflective surface and may be convexly or concavely curved.

The multi-layered structure typically is positioned at or on the reflective portions. In one embodiment the multi-layered structure is positioned between two panel components that have a mating cross-sectional shape.

The multi-layered structure may be positioned at or on each first reflective portion. Alternatively or additionally, the multi-layered structure may also be positioned at or on at least some or all of the second reflective portions. In a further alternative, the multi-layered structure is positioned at or on each first reflective portion and the second reflective portions are coated with another coating.

In an alternative embodiment the spectrally selective component may also comprise an arrangement that can be used to control an inclination of the reflective portions.

The reflective component may be arranged to reflect more than 60, 70, 80 or 90% of the incident radiation at a wavelengths range from approximately 300 nm to approximately 420 nm.

The reflective component may also be arranged such that within a wavelengths range from approximately 380 nm to approximately 420 nm the transmittance increases from less than 10% to more than 60%.

Further, the reflective component may be arranged to transmit more than 40%, 50%, 60%, 70%, 80% or 90% of incident radiation within a wavelengths range of approximately 400 nm to approximately 680-750 nm.

In one example the reflective component is arranged such that within a wavelengths range from approximately 600 nm to approximately 800 nm the transmittance decreases from at least 60% to less than 10%.

The reflective further component may also be arranged to reflect more than 90% of solar energy of the incident radiation at a wavelengths range of approximately 700 nm to approximately 1700 nm.

The spectrally selective panel may also comprise a scattering material that is arranged to increase scattering of incident radiation, such as a scattering material that predominantly scatters radiation having a wavelength in the IR wavelengths range. For example, the scattering material may comprise micro- or nano-sized particles and may be provided in the form of a film.

Scattering of radiation may be achieved in a substantially lossless (non-absorbing) manner within the IR and/or visible wavelengths range if for example scattering materials are used that have relatively wide energy band-gaps, such as particles of rare earth oxides (Yb₂O₃ or Nd₂O₃ for example).

The present invention provides in a second aspect a system comprising:
the spectrally selective panel in accordance with the first aspect of the present invention; and
at least one photovoltaic cell that is positioned to receive at least a portion of the redirected radiation to generate electricity.

The present invention provides in a third aspect a system comprising:
a spectrally selective panel that is arranged to direct at least a portion of incident radiation towards an edge of the spectrally selective panel;
an optical conduit that is coupled to an edge of the spectrally selective panel and positioned to guide at least a portion of radiation received at the edge of the panel; and
a light extractor coupled to the optical conduit and arranged such that the at least a portion of the guided radiation is extracted to illuminate a region.

In third aspect of the present invention the spectrally selective panel may also be provided in the form of the spectrally selective panel according to the first aspect of the present invention. The spectrally selective panel typically is arranged such that a portion of incident visible light is redirected within the spectrally selective panel.

The invention will be more fully understood from the following description of specific embodiments of the invention. The description is provided with reference to the accompanying drawings.

### BRIEF DESCRIPTION OF THE DRAWINGS

FIG. 1 is a representation of a spectrally selective panel in accordance with a specific embodiment of the present invention;

FIG. 2 is a schematic illustration of a component of the spectrally selective component in accordance with an embodiment of the present invention; and

FIGS. 3 and 4 are schematic illustrations of components of a system in accordance with an embodiment of the present invention.

### DETAILED DESCRIPTION OF SPECIFIC EMBODIMENTS

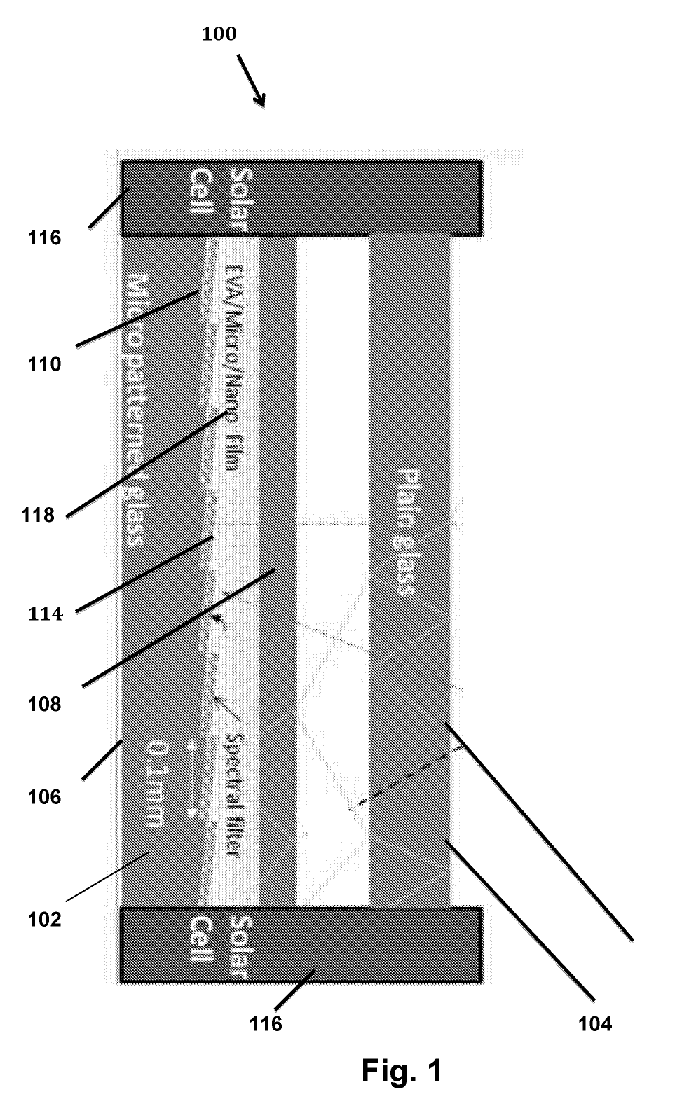

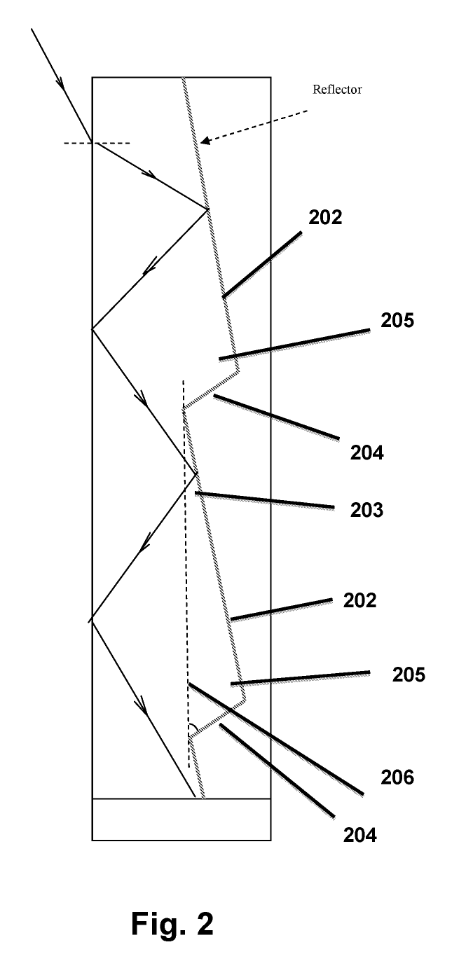

Referring now to FIGS. 1 and 2, a spectrally selective panel 100 is described. The spectrally selective panel 100 may for example be provided in the form of a windowpane of a building, car, ship or any other suitable object. In this embodiment the spectrally selective panel 100 reduces transmission of radiation having a wavelength in an IR wavelength band while being largely transmissive for visible light. IR radiation of a selected wavelengths range is in use the diverted to edges of the spectrally selective panel 100.

The spectrally selective panel 100 comprises a first panel 102 and a second panel 104. The first and second panels 102 and 104 are spaced apart such that an air gap is formed. In an alternative embodiment the gap may be filled with any other suitable dielectric material. The first panel 102 comprises panel portions 106 and 108 and the panel portion 106 has a profiled surface on which a multilayered optical interference coating 110 is positioned. The profiled surface together with the optical interference coating 110 forms a reflective component.

In another variation (not shown) the first panel 102 comprises two panel portions that both have profiled mating surfaces at which the multilayer coating is positioned and at which the panel portions are joined using a suitable optical adhesive.

The spectrally selective panel 100 has a receiving surface 112 via which radiation, such as sunlight, is received. The reflective component is arranged to reflect a portion of incident radiation that penetrated through the second panel 104 and through a depth portion of the first panel 102 to the reflective component. The reflective component comprises a series of reflective portions 114 that are inclined relative to the receiving surface 112 of the second panel 104. The reflective portions 114 are oriented and the layer 110 is arranged such that a portion of the received incident radiation is re-directed within and along the spectrally selective panel 100.

In this embodiment the reflective portions 114 are planar (flat), but may alternatively also have another suitable shape. For example, the reflective portions may have a rough surface that has optical properties that approximate those of a smooth and flat surface. The reflective portions 114 are inclined such that, when the panel 100 is positioned in a suitable vertical position, spectrally selected sunlight (dependent on properties of the layer 110) that is incident at an angle of 40 to 50 degrees above horizon is redirected and guided (facilitated by total internal reflection at interfaces) towards edges of the spectrally selective panel 100.

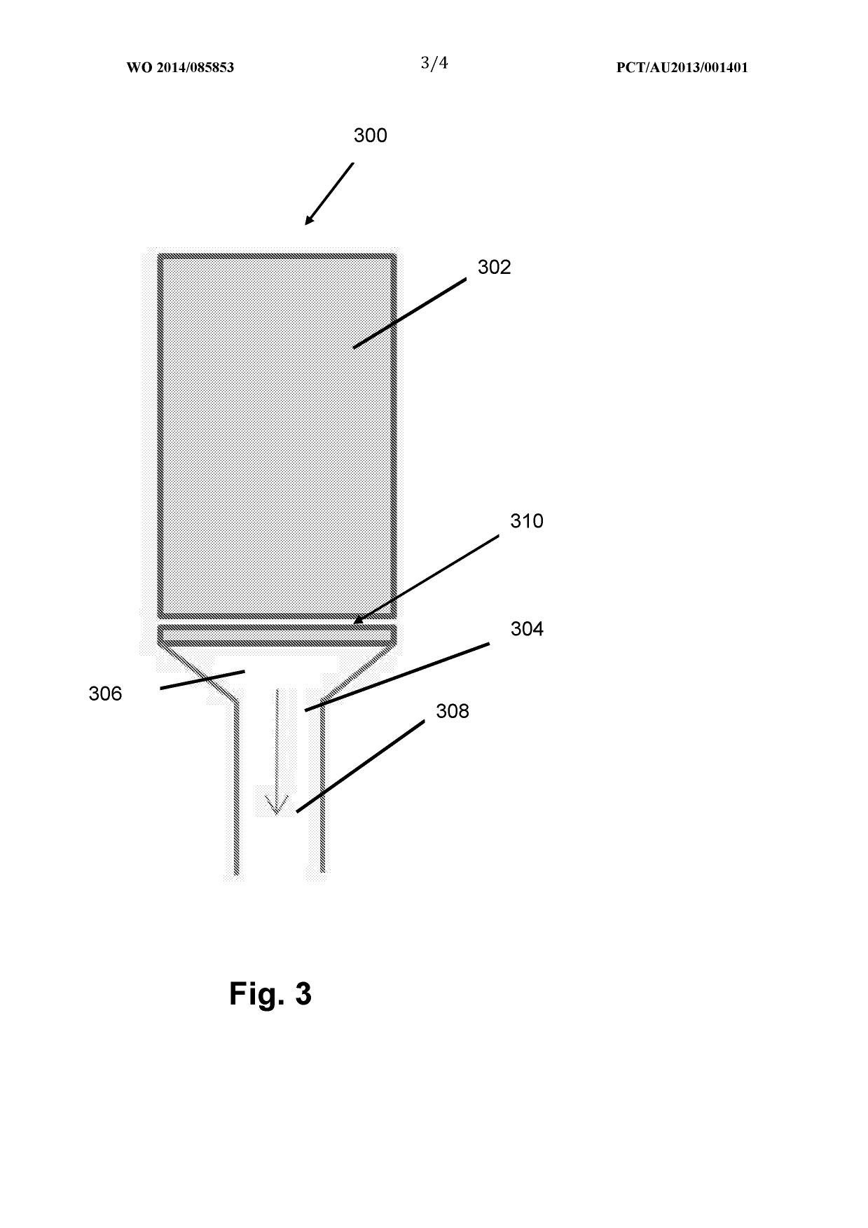

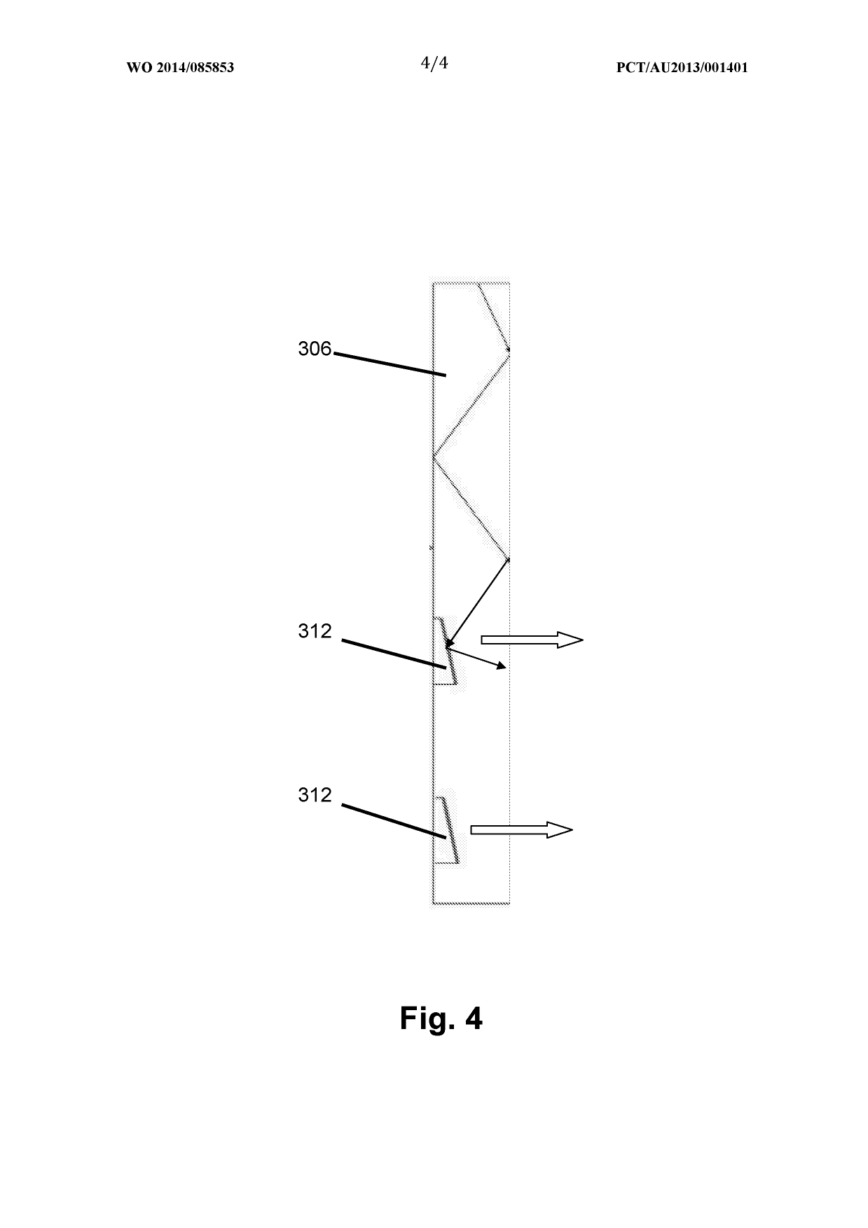

In this embodiment the spectrally selective panel 100 comprises photovoltaic cells 116 that receive the re-directed radiation and generate electricity. In a variation of the described embodiment the spectrally selective panel may not comprise the photovoltaic cells 116, but may alternatively comprise an optical coupler (not shown) with an optical light guide that is arranged to collect the radiation at edges of the panel 100 and guide the radiation to a light extractor for illumination of an interior space in a building. This embodiment will be described further below with reference to FIGS. 3 and 4.

The panel portions 106, 108 and the second panel 104 may be formed from any suitable material, such as glass or a polymeric material.

In this embodiment each reflective portion 114 is provided in the form of an elongated strip that may have any suitable length and a width of the order of 0.01-1 mm, 0.05-0.5, 0.7-0.3 mm, such as of the order of 0.1 mm. In an alternative embodiment each reflective portion 114 may also have a larger width, such as a width larger than 1 mm, 5 mm, 10 mm or 20 mm.

FIG. 2 illustrates schematically a possible geometrical arrangement of first and second reflective portions 202 and 204 that may replace the reflective portions 114 shown in FIG. 1. The first and second reflective portions 202, 204 form a series of reflective portions in which the first and second reflective portions 202, 204 alternate. The first reflective portions 202 are inclined by a first angle 203 of 12±5 degrees relative to a base surface 206 that is parallel to the receiving surface 112. The second reflective portions 204 are positioned such that the second reflective portions 204 form and second angle 205 of 106±5 degrees relative to adjacent first reflective portions 202. In this embodiment adjacent first and second reflective portions 202, 204 consequently are arranged such that a base plane 206 together with the adjacent first and second reflective portions 202, 204 have a triangular cross-sectional shape that has a first angle of 12±5 degrees, a second angle of 106±5 degrees and a third angle of 62±5 degrees. A person skilled in the art will appreciate that alternative variations are possible.

For example, not all first reflective portions may be inclined in the same manner. Further not all second reflective portions may be inclined in the same manner. The spectrally selective panel may comprise respective areas in which the first and second reflective portions are inclined in a respective manner. For example, the first and second reflective portions may form a “saw-tooth” like arrangement that is oriented in a first manner within a first area of the spectrally selective panel and the first and second reflective portions in a second area may be oriented in an opposite manner such that light is directed towards two opposite edges of the panel.

The multi-layered structure 110 is positioned at or on the reflective portions 114, 202 and 204. Alternatively, the multilayered structure may only be positioned on the reflective portions 114 and 202 and a different type of coating (or no coating) may be positioned on the reflective portions 204. In the embodiment illustrated in FIG. 1 the multi-layered structure 110 is positioned between the panel portions 106 and 108.

The multi-layered structure 110 is in this embodiment anti-reflective for visible light and reflective for incident UV radiation. Consequently, a portion of IR and UV radiation is reflected by the inclined reflective portions and re-directed towards edges of the panel 100. However, a person skilled in the art will appreciate that alternatively the multi-layered structure 110 may be arranged to redirected a portion of the visible light, which may be used for illumination of an interior portion of a building using suitable optical couplers, guides and light extractors.

Adjacent the multi-layered structure 110 is a further layer 118 that comprises in this embodiment nano- or micro-sized particles of rare earth oxides having a relatively wide energy bandgap such that scattering of suitable radiation is effectively lossless (non-absorbing). Further, the layer 118 comprises an epoxy that couples the panel portions 106 and 108. The layer 118 may also comprise luminescent materials.

FIGS. 3 and 4 illustrate a system in accordance with an embodiment of the present invention. The system 300 comprises a spectrally selective panel 302 that is largely identical to the spectrally selective panel 100 described with reference to FIG. 1, but does not comprise photovoltaic elements. The system 100 comprises an optical light coupler 304 that is positioned and arranged to receive light that is directed towards and edge of the panel 300. The optical light coupler 304 comprises a generally flat and substantially triangular portion 306 in which the light is directed by total internal reflection towards a light guide 308. The optical light coupler has an end-face 310 that has a shape that approximates that of an end-face of the panel 300 and is coupled to the panel 300 using a suitable optical gel.

The optical light guide 308 is arranged for directing light by total internal reflection and comprises reflector portions 312. The reflector portions 312 are positioned within the optical light guide 308 and are arranged to reflect the light out of the light guide 308. The reflector portions may for example be positioned within an interior portion of a building such that in use the panel 300, which may form a part of a window of the building, may collect daylight and the light guide 308 my direct the daylight form the optical light coupler 304 to the reflector portions 312 such that the daylight exits the light guide 306 and can be used for illumination of the interior of the building.

The optical coupler 304 and the light guide 308 typically have a rectangular cross-sectional shape and may comprise suitable optically transmissive materials, such as polymeric materials.

The multi-layered structure 110 will now be described in further detail. The multi-layered structure 110 is an edge-filter coating design type and is formed from layers comprising Al₂O₃, SiO₂ and Ta₂O₅ using RF sputtering techniques. The total thickness of such a coating is in this embodiment between 4-8 μm and the order of optical materials within a sequence of component layers may vary, depending on a chosen design. Annealing experiments (3 hrs at 600° C. with temperature ramp-rates of 5° C./min) demonstrated excellent mechanical, stress-exposure related, thermal exposure-related and adhesion stability.

The multi-layered structure 110 is arranged such that the fraction of total integrated solar-IR radiation power contained within the wavelengths range of 700-1700 nm and that transmits optically only approximately 4%. The multi-layered structure 110 has in this embodiment also a high reflectivity (>90% or even >98%) of solar radiation across a wide UV band of solar radiation within the general limits between 300-410 nm. Further, the multi-layered structure 110 has a rather steep spectral transmission response slope near approximately 400 nm, such that the radiation transmission raises from near-zero (sub 5%) level for the wavelengths just below 400-415 nm, to a significant optical transmission level exceeding 60-80% already within the adjacent violet radiation region near 400-420 nm. The steepness of this slope is defined as percentage of transmittance change per nanometre bandwidth. The multi-layered structure 110 has a UV-to-visible transmission-slope tangent of 8-10% T/nm, with the UV-to-visible transmission slopes positioned in the vicinity of 400 nm.

The “stability” of the visible transmission response region can be described by the ratio between the 80% T-level bandwidth (in nm) of the transmitted radiation band to the full width at half maximum bandwidth of the same transmission band. The multi-layered structure 110 has a response stability in excess of 0.9.

The multi-layered structure 110 is also arranged to have a steep spectral transmission response slope near approximately 700+/−100 nm, such that the transmittance decreases from the level within the visible band (typically over 60-80%) level for the wavelengths above 400+/−20 nm, but below 700+/−100 nm to a rather small optical transmission level not exceeding 5-10% already within the adjacent red or near-IR radiation region near the vicinity of 700 nm where the significant transmission change is engineered to occur.

The steepness of this spectral transmission-reduction slope can be characterised by the percentage of transmittance change per nanometre bandwidth. The multi-layered structure 110 is arranged such that the visible radiation band to the near-infrared solar radiation slope tangents is about −2.5-(−3) % T/nm with the visible-to-IR transmission response slopes typically positioned spectrally in the vicinity of either 700 nm (+/−20 nm) or 750 nm (+/−20 nm).

However, as mentioned above, the multi-layered structure 110 may alternatively also be arranged to have different reflective properties, and may be reflective for a portion of visible light (especially for applications in which the panel 100 is used to provide light for illumination of interior spaces).

The following will summarise the design of the multi-layered structure 110. The multi-layered structure 110 comprises layers of dielectric materials. Each of say 3 stacks comprises typically more than 10 component layers. Layer properties may be calculated as follows using a suitable software routine and a high-performance Needle Optimization or Random Optimization, or Genetic algorithms:

S{a}(L/2HL/2)^{m}{b}(L/2HL/2)ⁿ{c}(L/2HL/2)^{p}{d}(LMHML)^{q}

with S identifying the location of the substrate with respect of film sequence and L, H and M denoting the quarter-wave optical thickness layers of the corresponding materials. The design wavelength in each set of brackets is varied according to the preceding multiplication factor in the “{ }” brackets, with respect to a base design wavelength. For example for a design wavelength of 500 nm, the optical layer thicknesses in the sub-stack {2.0}(HLM)10 is calculated as being 1000 nm for all layers within that sub-stack within the “( )” brackets. Consequently, the physical thickness of each the layer “H” is 1000 nm/(4*n(H)).

The aim of the optimization algorithm is to minimise sub-stack repetition indices m, n, p, and q as well as minimise the total thickness and layer number required to achieve the desired spectral response shape for any given application. Another goal is to optimize the local (sub-stacks) individual design-wavelength multiplication factors a, b, c, and d. If desired, in any additional layers may be inserted into the sequence of layers, in between sub-stacks or any index-matching layers in order to further adjust a resultant performance and spectrum the multi-layered structure 110.

An example of one embodiment of this design approach is provided in the following: S{2.11}(L/2HL/2)¹²{1.64}(L/2HL/2)⁸{2.85}(L/2HL/2)⁸{1.4}(LMHM L)¹

A (base) design wavelength of 500 nm was used for the optimisation and the materials used were Ta₂O₅, Al₂O₃ and SiO₂. 61 layers in the deposition sequence (thickness ¼ of the wavelength of the radiation), total thickness of coating shown in this example is 9.4 μm.

Both the low-wavelength and the high-wavelength transmission slopes can be shifted spectrally and thus the slope locations can be controlled, through adjusting the design sequence and individual layer thicknesses. The high-transmission band is shifted towards the green-red region in this example, as well as a rather narrow short-wave-rejection band results from this example design.

Although the invention has been described with reference to particular examples, it will be appreciated by those skilled in the art that the invention may be embodied in many other forms.

1-22. (canceled)

23. A spectrally selective panel that is at least partially transmissive for radiation having a wavelength within the visible wavelengths range, the panel comprising:
first and second panel components that are joined using a suitable optical adhesive;
a receiving surface for receiving incident radiation;
at least one reflective component forming a part of an inner surface of one of the first and second panel components and being arranged to reflect a portion of received incident radiation that penetrated through a depth portion of the panel to the reflective component, the at least one reflective component comprising first and second reflective portions that form a series in which the first and second reflective portions alternate, the first reflective portions being inclined by a first angle relative to the receiving surface and the second reflective portions being inclined by a second angle relative to the first reflective portions; the at least one reflective component further comprising a multi-layered structure that is positioned at or on each first reflective portion, the multilayer structure being an optical interference coating that results in reflection of at least a portion of incident radiation within an infrared (IR) wavelength;
wherein a coating other than the multi-layered structure or no coating is positioned on each second reflective portion; and
wherein the panel is arranged such that at least a portion of reflected incident radiation is re-directed within the panel.

24. The spectrally selective panel of claim 23 wherein the spectrally selective panel has substantially flat exterior surfaces.

25. The spectrally selective panel of claim 23 wherein the spectrally selective panel is provided in the form of, or forms part of, a window pane.

26. The spectrally selective panel of claim 23 wherein the at least one reflective component is at least partially transmissive for radiation having a wavelength within the visible wavelength band.

27. The spectrally selective panel of claim 23 further comprising a luminescent material that is arranged to absorb at least a portion of incident and/or reflected radiation and emit radiation by luminescence.

28. The spectrally selective panel of claim 23 wherein the panel is arranged such that at least the majority of radiation of a spectrally selected wavelengths range that is in use incident at an angle of incidence within the range 30-90 degrees relative to a plane containing a normal of the receiving surface is redirected within the panel.

29. The spectrally selective panel claim 23 wherein the panel is arranged such that at least the majority of radiation of a spectrally selected wavelengths range that is in use incident at an angle of incidence within the range 60-90 degrees relative to a plane containing a normal of the receiving surface is redirected within the panel.

30. The spectrally selective panel of claim 23 wherein each reflective portion has a prism-shaped cross-sectional shape in a plane perpendicular to the receiving surface.

31. The spectrally selective panel of claim 23 wherein each reflective portion is elongated and has a width that is: (a) larger than 1 mm; or (b) larger than 5 mm; or (c) larger than 10 mm.

32. The spectrally selective panel of claim 23 wherein at least one of the reflective portions is inclined at an angle that is different to an angle of inclination of other reflective portions.

33. The spectrally selective panel of claim 32 wherein a first plurality of reflective portions is inclined in a first manner and a second plurality of the reflective portions is inclined in a second manner that is opposite the first manner.

34. The spectrally selective panel of claim 23 wherein the first angle is of the order of 5-20 degrees and wherein the second angle of 100-150 degrees.

35. The spectrally selective panel of claim 23 wherein the reflective portions have a non-planer reflective surface.

36. The spectrally selective panel of claim 35 wherein the reflective surface is convexly or concavely curved.

37. The spectrally selective panel of claim 23 wherein the reflective portions of the reflective component are integrally formed.

38. The spectrally selective panel of claim 23 wherein at least some of the reflective portions are formed separately and then assembled to form at least a portion of the reflective component.

39. The spectrally selective panel of claim 35 wherein adjacent first and second reflective portions arranged such that a base plane of the reflective component together with the adjacent first and second reflective portions have a substantially triangular cross-sectional shape.

40. The spectrally selective panel of claim 23 wherein the at least one reflective component is arranged to reflect more than 60, 80, or 90% of the incident radiation at a wavelengths range from approximately 300 nm to approximately 420 nm.

41. A system comprising:
the spectrally selective panel in accordance with claim 23; and
at least one photovoltaic cell that is positioned to receive at least a portion of the redirected radiation to generate electricity.

42. A system comprising:
the spectrally selective panel in accordance with claim 23;
an optical conduit that is coupled to an edge of the spectrally selective panel and positioned to guide at least a portion of radiation received at the edge of the panel; and
a light extractor coupled to the optical conduit and arranged such that the at least a portion of the guided radiation is extracted to illuminate a region.
